(19) United States
(12) Patent Application Publication
(10) Pub. No.: US 2025/0306267 A1
(43) Pub. Date: Oct. 2, 2025

(54) PACKAGE STRUCTURE HAVING RING RESONANT STRUCTURE AND METHOD OF FORMING THE SAME

(71) Applicant: Taiwan Semiconductor Manufacturing Company, Ltd., Hsinchu (TW)

(72) Inventors: Feng-Wei KUO, Hsinchu County (TW); Wen-Shiang Liao, Miaoli County (TW)

(73) Assignee: Taiwan Semiconductor Manufacturing Company, Ltd., Hsinchu (TW)

(21) Appl. No.: 18/624,145

(22) Filed: Apr. 2, 2024

(51) Int. Cl. G02B 6/12; G02B 6/293; H01L 23/00; H01L 25/16

(52) U.S. Cl. CPC G02B 6/12007; H01L 25/167; G02B 2006/12061; G02B 6/29343; H01L 24/08; H01L 24/16; H01L 2224/08145; H01L 2224/16227

(57) ABSTRACT

Provided is a package structure including an optical transmission structure and a method of forming the same. The package structure includes: an electronic die; and a photonic die bonding to the electronic die. The photonic die includes: a substrate; an interconnect structure disposed over the substrate; a semiconductor layer disposed between the substrate and the interconnect structure. The semiconductor layer includes: a first waveguide and a second waveguide extending along a first direction; and at least two ring resonant structures arranged along a second direction different from the first direction and disposed between the first and second waveguides. The at least two ring resonant structures are configured to optically couple the first waveguide to the second waveguide in the second direction.

### BACKGROUND

Silicon photonics using use silicon waveguides as interconnects to carry optical signals is compatible with the fabrication of integrated circuits (ICs). As compared to data transmission by conductive wires, silicon photonics may offer reduced power consumption, higher efficiency, lower latency, and higher bandwidth. Although existing silicon photonics are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1F illustrate cross-sectional views of intermediate stages in the formation of a package structure in accordance with some embodiments.

FIG. 2 illustrates a top view of a region of a semiconductor layer of FIG. 1A.

FIG. 3 illustrates a cross-sectional view of a package structure in accordance with some alternative embodiments.

FIG. 4 illustrates a cross-sectional view of a package structure in accordance with some other embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

An optical transmission structure may be included in a semiconductor device used for optical communication systems and may be realized in an optical device with input/output (I/O) waveguides. For example, the optical transmission structure includes a closed-loop waveguide serving as a resonator, and I/O waveguide(s) optically and horizontally coupled to the resonator in the coupling region for inputting signal light into the resonator and outputting signal light therefrom. When the light couples from the input waveguide into the resonator, the light intensity gradually increases due to constructive interference in the closed loop resonator, and outputs from the resonator to the output waveguide. The input waveguide and the output waveguide may be a single waveguide at two opposing ends or may be two discrete waveguides disposed at two opposing sides of the resonator. The optical resonator may be operable as an optical filter, since only selected wavelengths will be at resonance within the closed loop. In some examples, the optical ring resonator may form a micro-ring modulator for modulating a phase of optical signals traveling within the waveguide. In some examples, the optical ring resonator may form a wavelength division multiplexing which multiplexes optical signals onto an optical fiber by using different wavelengths of light. It has been observed that a silicon-on-insulator (SOI) photonic device having a ring resonator and an I/O waveguide that are formed in the same layer is sensitive to silicon patterning process because the coupling efficiency is impacted by non-uniform gap spacing between the optical transmission structure and the I/O waveguide due to patterning process variations.

In accordance with some embodiments, an optical transmission structure is provided to include a first waveguide and a second waveguide extending along a first direction; and at least two racetrack-shaped resonant structures arranged along a second direction different from the first direction and disposed between the first and second waveguides. The first waveguide, the second waveguide, and the racetrack-shaped resonant structures are physically separated from each other in the second direction. It should be noted that the racetrack-shaped resonant structures are overlapped with each other in the second direction. In this case, the coupling area between the racetrack-shaped resonant structures is greater than that between the circular resonant structures, so that the gap between the racetrack-shaped resonant structures and the first and second waveguides, and/or the gap between the racetrack-shaped resonant structures may be increased. Therefore, the coupling efficiency of the optical transmission structure can be effectively improved without being affected by the patterning process variations.

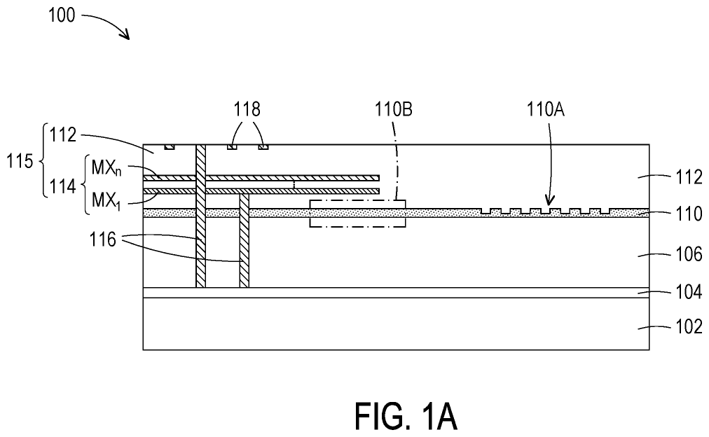

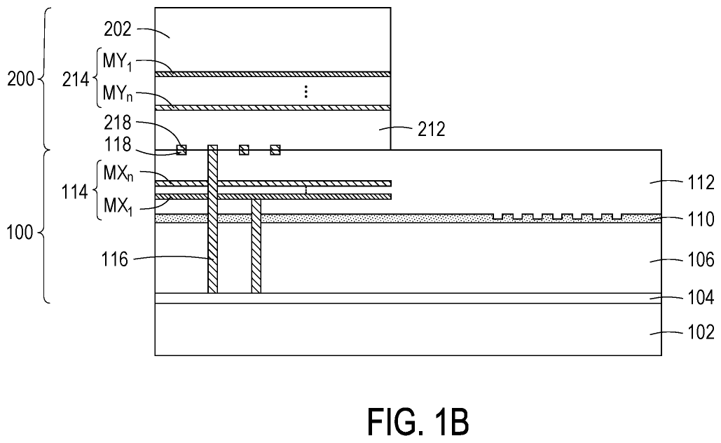

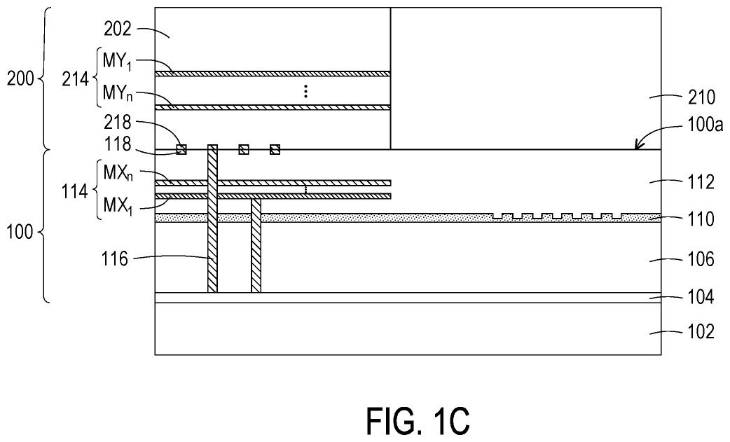

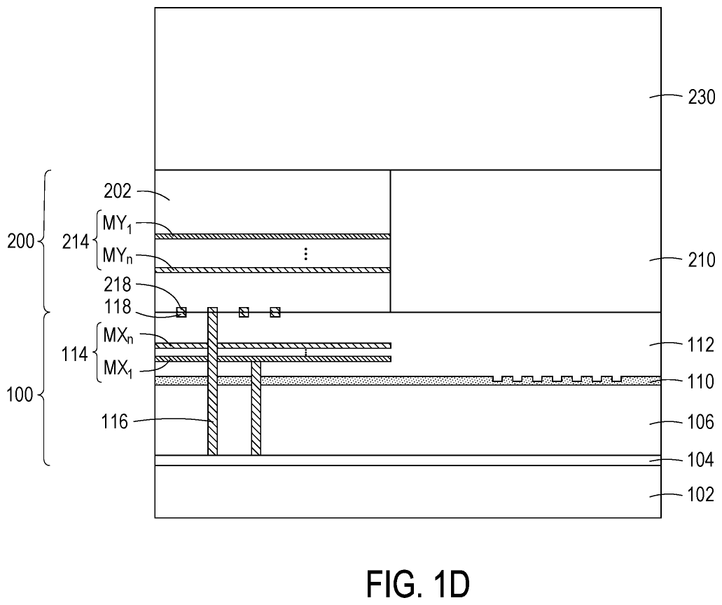

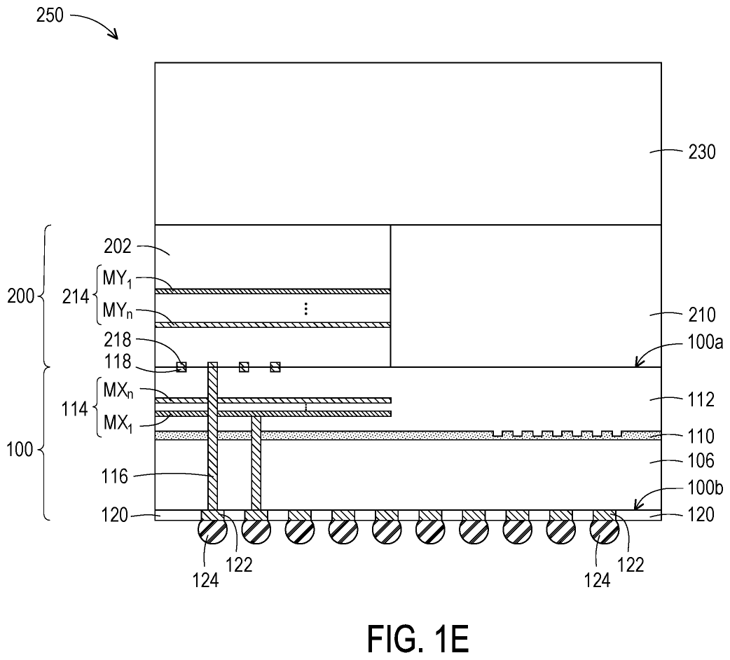

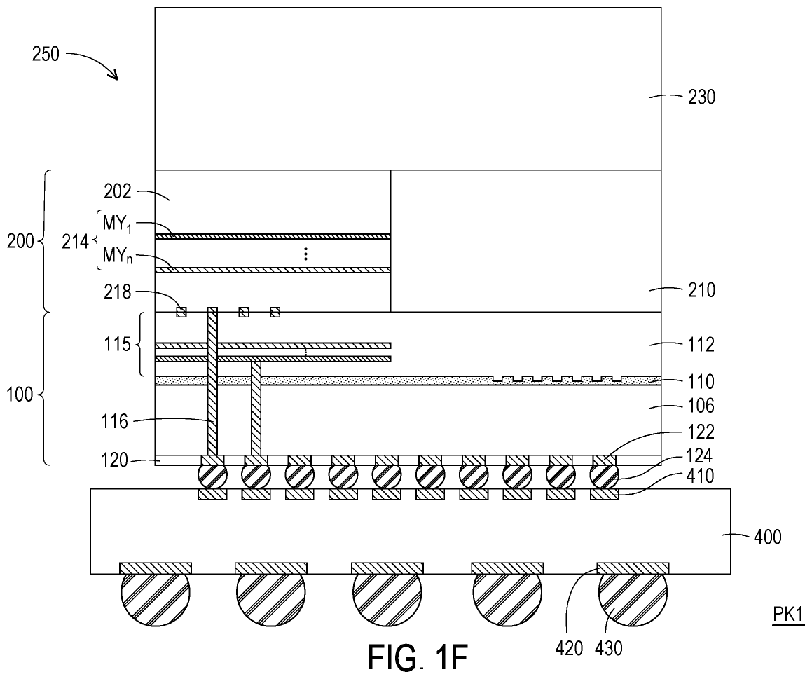

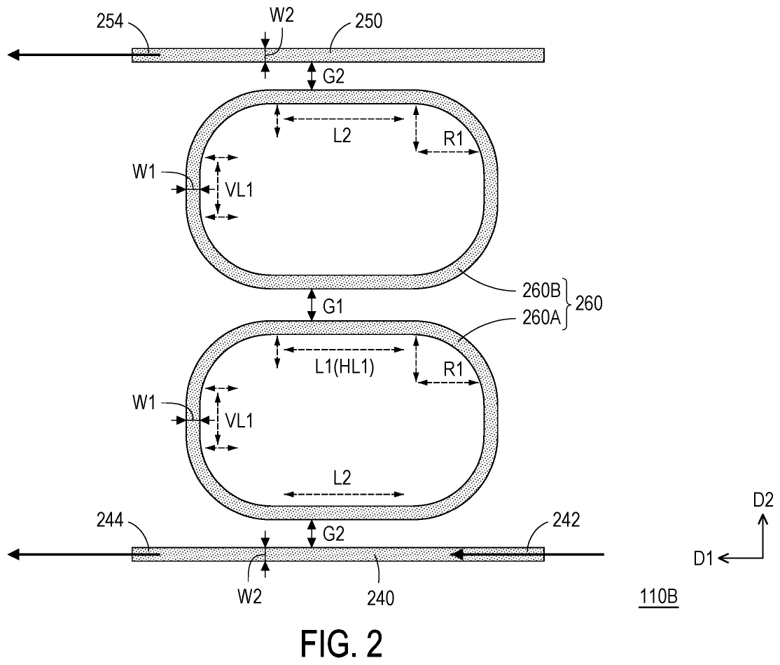

FIG. 1A to FIG. 1F illustrate cross-sectional views of intermediate stages in the formation of a package structure in accordance with some embodiments. FIG. 2 illustrates a top view of a region of a semiconductor layer of FIG. 1A.

Referring to FIG. 1A, a carrier 102 is provided. In some embodiments, the carrier 102 may be a glass carrier or any suitable carrier for carrying a semiconductor wafer or a reconstituted wafer for the manufacturing method of the stacked die package. In some embodiments, the carrier 102 is coated with a debond layer 104. The material of the debond layer 104 may be any material suitable for bonding and de-bonding the carrier 102 from the above layer(s) or any wafer(s) disposed thereon.

In some embodiments, the debond layer 104 may include a dielectric material layer made of a dielectric material including any suitable polymer-based dielectric material (such as benzocyclobutene (“BCB”), polybenzoxazole (“PBO”)). In an alternative embodiment, the debond layer 104 may include a dielectric material layer made of an epoxy-based thermal-release material, which loses its adhesive property when heated, such as a light-to-heat-conversion (LTHC) release coating film. In a further alternative embodiment, the debond layer 104 may include a dielectric material layer made of an ultra-violet (UV) glue, which loses its adhesive property when exposed to UV lights. In certain embodiments, the debond layer 104 may be dispensed as a liquid and cured, or may be a laminate film laminated onto the carrier 102, or may be the like. The top surface of the debond layer 104, which is opposite to a bottom surface contacting the carrier 102, may be levelled and may have a high degree of coplanarity. In certain embodiments, the debond layer 104 is, for example, a LTHC layer with good chemical resistance, and such layer enables room temperature de-bonding from the carrier 102 by applying laser irradiation, however the disclosure is not limited thereto.

Referring to FIG. 1A, a photonic die 100 is formed on the debond layer 104. Specifically, the photonic die 100 may include a substrate 106, a semiconductor layer 110, and an interconnect structure 115. The substrate 106 is disposed on the debond layer 104, and may have a bottom surface in contact with a top surface of the debond layer. In some embodiments, the substrate 106 is a dielectric substrate, such as silicon oxide substrate. However, other suitable dielectric materials are within the scope of the present disclosure. In some alternative embodiments, a reflector structure may be embedded in the substrate 106 to recycle leaked optic energy, thereby enhancing the coupler efficiency of the coupler 110A. In certain embodiments, a material of the reflector structure may include aluminum (Al), copper (Cu), ruthenium (Ru), manganese (Mn), titanium nitride (TiN), titanium (Ti), tantalum nitride (TaN), silicon nitride, combinations thereof, or the like.

The semiconductor layer 110 is disposed on the substrate 106. In some embodiments, the semiconductor layer 110 may include an optically transparent material and is configured to permit propagation of an optical signal. In this case, the semiconductor layer 110 may be referred to as an optical transmission structure and/or layer. In the present embodiment, the semiconductor layer 110 may be a silicon (Si) layer with a thickness in a range of about 100 nm to about 1000 nm, such as greater than 270 nm. In some alternative embodiments, the semiconductor layer 110 may be a silicon nitride (SiN) layer with a thickness in a range of about 100 nm to about 2000 nm, such as greater than 300 nm. Specifically, the semiconductor layer 110 may include one or more couplers 110A. As shown in FIG. 1A, the coupler 110A is illustrated as an example of a grating coupler having a plurality of trench patterns. In this case, the semiconductor layer 110 may be patterned through one or more etching steps to form the grating coupler having the same or different trench pattern depths. However, the embodiments of the present disclosure are not limited thereto. In some alternative embodiments, the coupler 110A may be an edge coupler.

In addition, the semiconductor layer 110 may include a region 110B. The top view of the region 110B of the semiconductor layer 110 is shown as FIG. 2. Specifically, the region 110B of the semiconductor layer 110 may include a first waveguide 240, a second waveguide 250, and at least two ring resonant structures 260. In such embodiment, the first waveguide 240, the second waveguide 250, and the ring resonant structures 260 may have the same material, such as silicon or silicon nitride. The semiconductor layer 110 may be patterned through one or more etching steps to form the first waveguide 240, the second waveguide 250, and the ring resonant structures 260 with the same etching depth. In some embodiments, the etching depth may be in a range of about 0 nm to about 1000 nm, such as greater than 70 nm when the semiconductor layer 110 is made of silicon. In some alternative embodiments, the etching depth may be in a range of about 0 nm to about 2000 nm, such as greater than 150 nm when the semiconductor layer 110 is made of silicon nitride.

In some embodiments, the first waveguide 240 and the second waveguide 250 extending along a first direction D1. The ring resonant structures 260 may include a first ring resonant structure 260A and a second ring resonant structure 260B arranged along a second direction D2 different from the first direction D1. In some embodiments, the first direction D1 is substantially orthogonal to the second direction D2. The ring resonant structures 260 may be disposed between the first waveguide 240 and the second waveguide 250 in the second direction D2. The first ring resonant structure 260A, the second ring resonant structure 260B, the first waveguide 240, and the second waveguide 250 may be physically separated from each other in the second direction D2. That is, the first ring resonant structure 260A, the second ring resonant structure 260B, the first waveguide 240, and the second waveguide 250 would not contact to each other.

As shown in FIG. 2, the first waveguide 240 may include an input port 242 and a through port 244, and the second waveguide 250 may include a drop port 254. In some embodiments, the ring resonant structures 260 may be configured to optically couple the first waveguide 240 to the second waveguide 250. In this case, the first waveguide 240 and the second waveguide 250 may be referred to as input/output (I/O) waveguides, and the ring resonant structures 260 may be referred to as micro-ring resonators or optical resonators. The input port 242 of the first waveguide 240 may be optically connected to the coupler 110A (FIG. 1), and the input port 242 may be configured to receive an incident optical signal and couple the incident optical signal into the first waveguide 240. The through port 244 of the first waveguide 240 may be optically connected to a first photodetector (e.g., photodiode), and the through port 244 may be configured to emit the optical signal from the first waveguide 240 to the first photodetector. The drop port 254 of the second waveguide 250 may be optically connected to a second photodetector, and the drop port 254 may be configured to emit the optical signal from the second waveguide 250 to the second photodetector. The first and second photodetectors are both electrically connected to an electronic circuit of the device layer. The electronic circuit (not shown) may be configured to receive electrical signals from the first and second photodetector. The electronic circuit may be configured to use the electrical signals to perform a function for implementation of a designed functionality of the IC. In some embodiments, the electronic circuit may include memory, logic circuitry or other suitable components.

The ring resonant structures 260 may be configured to optically couple the first waveguide 240 to the second waveguide 250. The ring resonant structures 260 may be positioned close to, but not in contact with, each of the first waveguide 240 and the second waveguide 250. A size of the gap between the ring resonant structures 260 and each of the first waveguide 240 and the second waveguide 250 determines the coupling efficiency between the ring resonant structures 260 and the corresponding waveguide. Light coupled from the first waveguide 240 into the ring resonant structures 260 travels in a counter-clockwise direction, based on the arrow at the input port 242. The light intensifies due to constructive interference within the ring resonant structures 260. The light is then able to be coupled from the ring resonant structures 260 into the second waveguide 250 and output in the direction indicated by the arrow at the drop port 254. That is, the first waveguide 240, the second waveguide 250, and the ring resonant structures 260 may be at the same level, so that the optical signal is transmitted horizontally on the same plane.

It should be noted that each of the ring resonant structures 260 is racetrack-shaped in a top view of the semiconductor layer 110. Specifically, an overlapping length L1 of facing sidewalls of the ring resonant structures 260 in the first direction D1 is at least greater than zero. In some embodiments, the overlapping length L1 may be in a range of about greater than 0 μm to about 500 μm, such as 5 μm. Selecting the overlapping length L1 of greater than 0 μm provides sufficient coupling area between the first ring resonant structure 260A and the second ring resonant structure 260B. Selecting the overlapping length L1 of no more than 500 μm allows for miniaturization of the photonic die 100, especially the optical transmission structure 100. In the present embodiment, the first ring resonant structure 260A and the second ring resonant structure 260B are completely aligned and overlapped with each other in the second direction D2, as shown in FIG. 2. In this case, the gap G1 between the first ring resonant structure 260A and the second ring resonant structure 260B in the second direction D2 may be increased. As a result, the coupling efficiency between the first ring resonant structure 260A and the second ring resonant structure 260B can be effectively improved without being affected by the patterning process variations. In such embodiment, the gap G1 may be in a range of about 10 nm to about 500 nm, such as greater than 60 μm. Selecting the gap G1 of greater than 10 nm provides sufficient patterning process window without affecting the coupling efficiency between the first ring resonant structure 260A and the second ring resonant structure 260B. Selecting the gap G1 of no more than 500 nm allows for miniaturization of the photonic die 100, especially the optical transmission structure 100.

In addition, an overlapping length L2 of facing sidewalls of the ring resonant structures 260 and the first/second waveguide 240/250 in the first direction D1 is also at least greater than zero. In some embodiments, the overlapping length L2 may be in a range of about greater than 0 μm to about 500 μm, such as 5 μm. Selecting the overlapping length L2 of greater than 0 μm provides sufficient coupling area between the ring resonant structures 260 and the first/second waveguide 240/250. Selecting the overlapping length L2 of no more than 500 μm allows for miniaturization of the photonic die 100, especially the optical transmission structure 100. In this case, the gap G2 between the ring resonant structures 260 and the first/second waveguide 240/250 in the second direction D2 may be increased. As a result, the coupling efficiency between the ring resonant structures 260 and the first/second waveguide 240/250 can be effectively improved without being affected by the patterning process variations. In such embodiment, the gap G2 may be in a range of about 10 nm to about 500 nm, such as greater than 60 μm. Selecting the gap G2 of greater than 10 nm provides sufficient patterning process window without affecting the coupling efficiency between the ring resonant structures 260 and the first/second waveguide 240/250. Selecting the gap G2 of no more than 500 nm allows for miniaturization of the photonic die 100, especially the optical transmission structure 100.

In some embodiments, the first ring resonant structure 260A and the second ring resonant structure 260B have the same racetrack shape in the top view of the semiconductor layer 110. Specifically, each of the ring resonant structures 260 may have a radius R1, a horizontal length HL1, a vertical length VL1, and a rib width W1. In some embodiments, the radius R1 may be in a range of about 1 μm to about 50 μm, such as greater than 5 μm; the horizontal length HL1 may be in a range of about greater than 0 μm to about 500 μm, such as 5 μm; the vertical length VL1 may be in a range of about greater than 0 μm to about 100 μm, such as 4 μm; and the rib width W1 may be in a range of about 100 nm to about 1000 nm, such as greater than 370 nm. In some alternative embodiment, the rib width W1 may be in a range of about 500 nm to about 3000 nm, such as greater than 500 nm, when the semiconductor layer 110 is made of silicon nitride. The top view shapes of the first ring resonant structure 260A and the second ring resonant structure 260B are identical in the wavelength division multiplexing (WDM) device. However, the embodiments of the present disclosure are not limited thereto. In some alternative embodiments, the top view shape of the first ring resonant structure 260A may be different from that of the second ring resonant structure 260B in other devices.

Further, as shown in FIG. 2, the first waveguide 240 and the second waveguide 250 have the same rib with W2. In some embodiments, the rib width W2 may be in a range of about 100 nm to about 1000 nm, such as greater than 370 nm, when the semiconductor layer 110 is made of silicon. In some alternative embodiment, the rib width W2 may be in a range of about 500 nm to about 3000 nm, such as greater than 500 nm, when the semiconductor layer 110 is made of silicon nitride.

Although the ring resonant structures 260 illustrated in FIG. 2 include two ring resonant structures, alternate implementations of the ring resonant structures 260 may include three, four, five, and/or other quantities of ring resonant structures. Compared with single ring resonant structure, selecting at least two ring resonant structures can reduce loss, enhance cross talk function, obtain better bandwidth, and have better filter function.

Referring back to FIG. 1A, the interconnect structure 115 may be disposed on the semiconductor layer 110, so that the semiconductor layer 110 is vertically sandwiched between the substrate 106 and the interconnect structure 115. Specifically, the interconnect structure 115 may include a dielectric layer 112 and an interconnection layer 114 formed within the dielectric layer 112. In some embodiments, the dielectric layer 112 may be an oxide layer such as silicon oxide, or the like. In some embodiments, the interconnection layer 114 may include a plurality of metallization layers MX₁˜MXₙ (where n is an integer of 2 or more) stacked up over the semiconductor layer 110 and embedded in the dielectric layer 112. In one exemplary embodiment, there are six metallization layers MX₁˜MX₆ embedded in the dielectric layer 112.

In some embodiments, a plurality of through dielectric vias 116 are formed in the dielectric layer 112. In some embodiments, some of the through dielectric vias 116 are electrically connected to the plurality of metallization layers MX₁˜MXₙ, while some of the through dielectric vias 116 may pass through the interconnection layer 114, the dielectric layer 112, the semiconductor layer 110, and the substrate 106 and extend towards the debond layer 104. That is, some of the through dielectric vias 116 may extend between the top surface of the dielectric layer 112 and the top surface of the debond layer 104. The photonic die 100 further includes a plurality of connection pads 118 disposed within the dielectric layer 112. In some embodiments, the connection pads 118 may exposed at the top surface of the dielectric layer 112. In some embodiments, the top surface of a portion of the through dielectric vias 116 is substantially coplanar and aligned with the top surface of the connection pads 118, and substantially aligned with the top surface of the dielectric layer 112 to facilitate subsequent bonding steps.

Referring to FIG. 1B, in a subsequent step, an electronic die 200 is stacked on the photonic die 100. In some embodiments, the electronic die 200 is attached and bonded to the photonic die 100 through directly bonding (e.g., hybrid bonding). In some embodiments, the electronic die 200 includes a dielectric layer 202, an interconnection layer 214 embedded in the dielectric layer 202 and a plurality of bonding pads 218 exposed at a surface of the dielectric layer 202. In some embodiments, the interconnection layer 214 include a plurality of metallization layers MY₁˜MYₙ (where n is an integer of 2 or more) embedded in the dielectric layer 202. In certain embodiments, some of the bonding pads 218 are electrically connected to the metallization layers MY₁˜MYₙ by a plurality of through vias (not shown). Furthermore, the bonding pads 218 of the electronic die 200 are electrically connected and bonded to the connection pads 118 of the photonic die 100. The through dielectric vias 116 of the photonic die 100 may be electrically connected and attached to some of the bonding pads 218 of the electronic die 200. In some embodiments, the connection pads 118 of the photonic die 100 may be in direct contact with some of the bonding pads 218 of the electronic die 200, the through dielectric vias 116 of the photonic die 100 may be in direct contact with other of the bonding pads 218 of the electronic die 200, and the dielectric layer 112 of the photonic die 100 may be in direct contact with the dielectric layer 212 of the electronic die 200, thereby forming a hybrid bonding structure. In some embodiments, the bonding between the electronic die 200 and the photonic die 100 may not include any bump structure, i.e., bumpless. However, in some other embodiments, the bonding between the electronic die 200 and the photonic die 100 may be established through a number of bump structures. For example, the bonding may be hybrid bonding, fusion bonding, direct bonding, dielectric bonding, metal bonding, solder joints (e.g., microbumps), or the like.

In some embodiments of the present disclosure, the electronic die 200 acts as a central processing unit, which includes controlling circuits for controlling the operation of the devices in photonic die 100. In addition, electronic die 200 may include the circuits for processing the electrical signals converted from the optical signals in photonic die 100. In certain embodiments, electronic die 200 may include driver circuitry for controlling optical modulators in the photonics die 100 and gain amplifiers for amplifying the electrical signals received from the photodetectors in photonic die 100. Electronic die 200 may also exchange electrical signals with photonic die 100. The photonic die 100 has the function of receiving optical signals, transmitting the optical signals inside the photonic die 100, transmitting the optical signals out of photonic die 100, and/or communicating electronically with the electronic die 200. In some embodiments, the photonic die 100 is also responsible for the Input-Output (IO) of the optical signals and/or electrical signals. By the bonding of the electronic die 200 and the photonics die 100, the distance between the electronic die 200 and the photonics die 100 can be effectively shortened to increase the transmission speed of the electrical and/or optical signals, thereby improving performance of the die stack structure. In this case, the bonding of the electronic die 200 and the photonics die 100 is also beneficial to miniaturization of package structure.

Referring to FIG. 1C, after bonding the electronic die 200 to the photonic die 100, a gap filling layer 210 is formed on a first surface 100a of the photonic die 100 to surround the electronic die 200. The gap filling layer 210 is an oxide layer, for example. In some embodiments, a sidewall of the gap filling layer 210 is substantially aligned with a sidewall of the photonic die 100. In some embodiments, at least one side surface of the electronic die 200 is not covered by the gap filling layer 210, and such side surface is aligned with the side surface of the photonic die 100. However, the disclosure is not limited thereto. In alternative embodiments, depending on the size of the electronic die 200, the gap filling layer 210 may be disposed on the photonic die 100 to surround all side surfaces of the electronic die 200.

Referring to FIG. 1D, after forming the gap filling layer 210, a support carrier 230 may be formed on the electronic die 200 and the gap filling layer 210. In some embodiments, the support carrier 230 may entirely cover the whole top surfaces of the electronic die 200 and the gap filling layer 210. In the present embodiment, the support carrier 230 may be a silicon carrier. However, the embodiments of the present disclosure are not limited thereto. In some alternative embodiments, the support carrier 230 may be a glass carrier, a silicon oxide carrier, an organic carrier, or the like.

Referring to FIG. 1D and FIG. 1E, in a subsequent step, the carrier 102 is de-bonded and is separated from the substrate 106. For example, the de-bonding process includes projecting a light such as a laser light or an UV light on the debond layer 104 (e.g., the LTHC release layer) so that the carrier 102 can be easily removed along with the debond layer 104. After the de-bonding process, a backside surface of the substrate 106 and backside surfaces of the through dielectric vias 116 may be revealed or exposed. That is, a second surface 100b of the photonic die 100 opposite to the first surface 100a may be exposed. After removing the carrier 102 and the debond layer 104, a dielectric layer 120 and a plurality of conductive pads 122 embedded in the dielectric layer 120 may be formed on the second surface 100b of the photonic die 100. In some embodiments, the conductive pads 122 and the electronic die 200 are located on two opposing surfaces of the photonic die 100. Some of the conductive pads 122 may be electrically connected to the through dielectric vias 116. Furthermore, a material of the conductive pads 122 may include a metal material (e.g., copper, aluminum copper, or the like), for example.

After forming the dielectric layer 120 and the conductive pads 122, a plurality of conductive connectors 124 may be formed on the second surface 100b of the photonic die 100 to contact and electrically connected to the conductive pads 122 for bonding the photonic die 100 to other components. In some embodiments, the conductive connectors 124 include solder regions, metal pillars, metal pads, metal bumps (sometimes referred to as micro-bumps), or the like. The material of the conductive connectors 124 may include non-solder materials, which may be formed of or comprise copper, nickel, aluminum, gold, multi-layers thereof, alloys thereof, or the like. The conductive connectors 124 may be electrically connected to the electronic die 200 through the conductive pads 122, the through dielectric vias 116, the interconnection layer 114, and the connection pads 118.

Referring to FIG. 1E and FIG. 1F, an overlying structure 250 of FIG. 1E may be bonded to a circuit substrate 400 through the conductive connectors 124, thereby accomplishing a package structure PK1. In some embodiments, the circuit substrate 400 may be an organic flexible substrate or a printed circuit board, for example. In some embodiments, the circuit substrate 400 includes contact pads 410, contact pads 420, metallization layers and vias (not shown) disposed in between the contact pads 410 and the contact pads 420. The contact pads 410 and the contact pads 420 are respectively distributed on two opposite sides of the circuit substrate 400, and are exposed for electrically connecting with later-formed elements/features. In some embodiments, the metallization layers and the vias are embedded in the circuit substrate 400 and together provide routing function for the circuit substrate 400. For example, the metallization layers and the vias may be electrically connected to some of the contact pads 410 and some of the contact pads 420. In some embodiments, the contact pads 410 and the contact pads 420 may include metal pads or metal alloy pads.

The overlying structure 250 may be bonded to the circuit substrate 400 by physically connecting the conductive connectors 124 to the contact pads 410 of the circuit substrate 400. In other words, the overlying structure 250 may be electrically connected to the circuit substrate 400 through the conductive connectors 124. In some embodiments, a plurality of conductive terminals 430 are formed over the circuit substrate 400. For example, the conductive terminals 430 are electrically connected to the contact pads 420 of the circuit substrate 400. Through the contact pads 410 and the contact pads 420, some of the conductive terminals 430 are electrically connected to the photonic die 100 or electronic die 200. In some embodiments, the conductive terminals 430 are, for example, solder balls or ball grid array (BGA) balls.

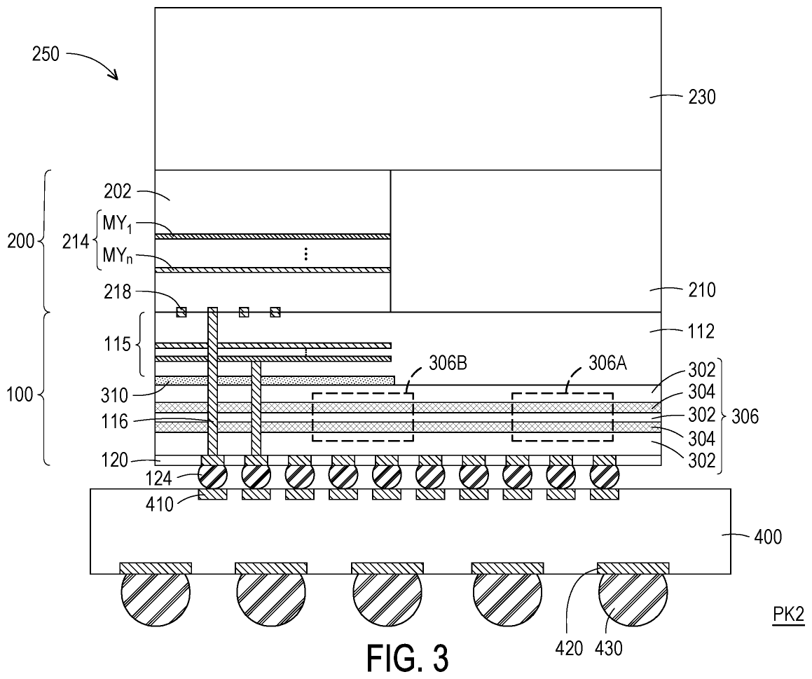

FIG. 3 illustrates a package structure PK2 in accordance with some alternative embodiments. Unless specified otherwise, like reference numerals in this embodiment (and subsequently discussed embodiments) represent like components in the embodiment shown in FIG. 1A through FIG. 2 formed by like processes. Accordingly, the process steps and applicable materials may not be repeated herein.

The package structure PK2 illustrated in FIG. 3 differs from the package structure PK1 illustrated in FIG. 1F in that the substrate 106 and the semiconductor layer 110 are replaced by a composite substrate 306 and a semiconductor layer 310 respectively. Specifically, the composite substrate 306 may be a stack structure having a plurality of first dielectric layers 302 and a plurality of second dielectric layers 304 stacked alternately. In some embodiments, the first dielectric layers 302 and the second dielectric layers 304 have different dielectric materials. For example, the first dielectric layers 302 are silicon oxide layers, while the second dielectric layers 304 are silicon nitride layers. In the present embodiment, the first dielectric layers 302 (e.g., the SiO layer) may have a thickness in a range of about greater than 0 μm to about 10 μm, such as greater than 0.1 μm; and the second dielectric layers 304 (e.g., the SiN layer) may have a thickness in a range of about 100 nm to about 2000 nm, such as greater than 300 nm.

Although the first dielectric layers 302 illustrated in FIG. 3 include three first dielectric layers and the second dielectric layers 304 illustrated in FIG. 3 include two second dielectric layers, the embodiments of the present disclosure are not limited thereto. In other embodiments, the number of the first dielectric layers 302 and the second dielectric layers 304 can be adjusted by the needs.

As shown in FIG. 3, the composite substrate 306 may include a first region 306A and a second region 306B. The first region 306A may have one or more couplers formed in one or more SiN layers 304, so as to couple the incident optical signal into the waveguides. The second region 306B may include an optical transmission structure formed in one or more SiN layers 304, wherein the optical transmission structure at least includes a first waveguide, a second waveguide, and at least two ring resonant structures. The first waveguide, the second waveguide, and the ring resonant structures formed in formed in one or more SiN layers 304 of the second region 306B are similar to those of the region 110B illustrated in the top view of FIG. 2. The configuration and the material of the first waveguide 240, the second waveguide 250, and the ring resonant structures 260 have been described in detail in the above embodiment and will not be repeated herein.

In some embodiments, each of the ring resonant structures formed in formed in one or more SiN layers 304 is racetrack-shaped in the top view. Specifically, the racetrack-shaped resonant structures are partially or completely overlapped with each other. In this case, the gap between the racetrack-shaped resonant structures may be increased. As a result, the coupling efficiency between the racetrack-shaped resonant structures can be effectively improved without being affected by the patterning process variations. On the other hand, the overlapping length between the racetrack-shaped resonant structures and the first/second waveguide is greater than that between the circular resonant structures and the first/second waveguide. In this case, the gap between the racetrack-shaped resonant structures and the first/second waveguide may be increased. As a result, the coupling efficiency between the racetrack-shaped resonant structures and the first/second waveguide can be effectively improved without being affected by the patterning process variations.

In addition, the semiconductor layer 310 of FIG. 3 may be referred to as a device layer of the photonic die 100. In some embodiments, the device layer 310 is formed on the composite substrate 306 in a front-end-of-line (FEOL) process. The device layer 310 includes a wide variety of devices. In some embodiments, the devices comprise active components, passive components, or a combination thereof. In some embodiments, the devices may include integrated circuits devices. The devices are, for example, transistors, capacitors, resistors, diodes, photodiodes, fuse devices, or other similar devices. In some embodiments, the semiconductor layer 310 and the second dielectric layers 304 have different materials. For example, the semiconductor layer 310 is a Si layer, and the second dielectric layers 304 are SiN layers. In this case, the optical signal may be transmitted horizontally along the optical transmission structure formed in the SiN layers 304, and the optical transmission structure formed in the SiN layers 304 may be optically coupled to the devices (e.g., photodiodes) in the Si layer 310 in a vertical manner.

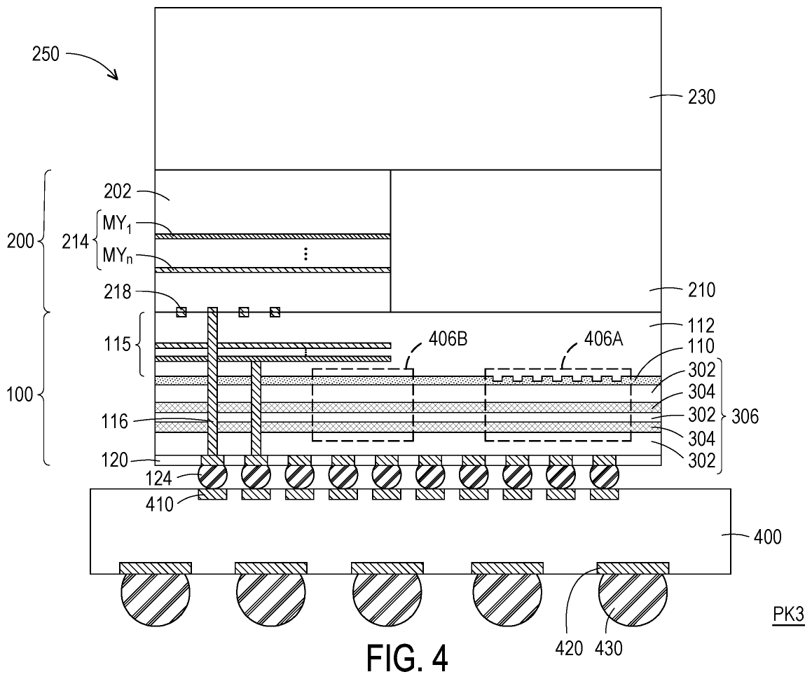

FIG. 4 illustrates a package structure PK3 in accordance with some other embodiments. Unless specified otherwise, like reference numerals in this embodiment (and subsequently discussed embodiments) represent like components in the embodiment shown in FIG. 1A through FIG. 2 formed by like processes. Accordingly, the process steps and applicable materials may not be repeated herein.

The package structure PK3 illustrated in FIG. 4 differs from the package structure PK1 illustrated in FIG. 1F in that the substrate 106 is replaced by a composite substrate 306. Specifically, the composite substrate 306 may be a stack structure having a plurality of first dielectric layers 302 and a plurality of second dielectric layers 304 stacked alternately. In some embodiments, the first dielectric layers 302 and the second dielectric layers 304 have different dielectric materials. For example, the first dielectric layers 302 are silicon oxide layers, while the second dielectric layers 304 are silicon nitride layers.

Although the first dielectric layers 302 illustrated in FIG. 4 include three first dielectric layers and the second dielectric layers 304 illustrated in FIG. 4 include two second dielectric layers, the embodiments of the present disclosure are not limited thereto. In other embodiments, the number of the first dielectric layers 302 and the second dielectric layers 304 can be adjusted by the needs.

As shown in FIG. 4, the photonic die 100 may include a first region 406A and a second region 406B. The first region 406A may have one or more couplers formed in the semiconductor layer 110 and/or one or more SiN layers 304, so as to couple the incident optical signal into the waveguides. The second region 406B may include an optical transmission structure formed in the semiconductor layer 110 and/or one or more SiN layers 304, wherein the optical transmission structure may include a first waveguide, a second waveguide, and at least two ring resonant structures. The first waveguide, the second waveguide, and the ring resonant structures formed in the second region 406B of the photonic die 100 are similar to those of the region 110B illustrated in the top view of FIG. 2. The configuration and the material of the first waveguide 240, the second waveguide 250, and the ring resonant structures 260 have been described in detail in the above embodiment and will not be repeated herein.

In some embodiment, one or more couplers (e.g., couplers 110A in FIG. 1A) formed in the semiconductor layer 110 may couple the incident optical signal into the waveguides (e.g., first waveguide 240). As shown in FIG. 2, the ring resonant structures 260 may be configured to optically couple the first waveguide 240 to the second waveguide 250. Specifically, light coupled from the first waveguide 240 into the ring resonant structures 260 travels in a counter-clockwise direction, based on the arrow at the input port 242. The light intensifies due to constructive interference within the ring resonant structures 260. The light is then able to be coupled from the ring resonant structures 260 into the second waveguide 250 and output in the direction indicated by the arrow at the drop port 254. That is, the first waveguide 240, the second waveguide 250, and the ring resonant structures 260 may be at the same level, so that the optical signal is transmitted horizontally on the same plane (e.g., Si layer 110).

On the other hand, one or more couplers formed in one or more SiN layers 304 may couple the incident optical signal into the SiN waveguides. The at least two racetrack-shaped resonant structures formed in one or more SiN layers 304 may be configured to optically couple the first waveguide to the second waveguide. In this case, the optical signal may be transmitted horizontally along the optical transmission structure formed in the SiN layers 304, and the optical transmission structure formed in the SiN layers 304 may be optically coupled to the devices (e.g., photodiodes) in the Si layer 110 in a vertical manner. In such embodiment, the optical signals may include horizontal and vertical transmission paths to make the layout of the optical path more flexible.

According to some embodiments, a package structure includes: an electronic die; and a photonic die bonding to the electronic die. The photonic die includes: a substrate; an interconnect structure disposed over the substrate; a semiconductor layer disposed between the substrate and the interconnect structure. The semiconductor layer includes: a first waveguide and a second waveguide extending along a first direction; and at least two ring resonant structures arranged along a second direction different from the first direction and disposed between the first and second waveguides. The at least two ring resonant structures are configured to optically couple the first waveguide to the second waveguide in the second direction.

In some embodiments, the first direction is substantially orthogonal to the second direction. In some embodiments, the at least two ring resonant structures are racetrack-shaped in a top view of the semiconductor layer, and an overlapping length of facing sidewalls of the at least two ring resonant structures in the first direction is at least greater than zero. In some embodiments, the at least two ring resonant structures are racetrack-shaped in a top view of the semiconductor layer, and the at least two ring resonant structures are completely aligned and overlapped with each other in the second direction. In some embodiments, the at least two ring resonant structures, the first waveguide, and the second waveguide are physically separated from each other in the second direction. In some embodiments, the at least two ring resonant structures have the same racetrack shape in a top view of the semiconductor layer. In some embodiments, the semiconductor layer is a silicon layer. In some embodiments, further comprising: a coupler optically connected to the first waveguide; a first photodetector optically connected to the first waveguide; and a second photodetector optically connected to the second waveguide. In some embodiments, further comprising: a dielectric layer embedded in the substrate, wherein the dielectric layer comprises at least two racetrack-shaped resonant structures. In some embodiments, the at least two racetrack-shaped resonant structures are optically coupled to the semiconductor layer in a vertical manner. In some embodiments, a material of the dielectric layer is silicon nitride.

According to some embodiments, a method of forming a package structure includes: bonding an electronic die to a photonic die, wherein the photonic die comprises an optical transmission structure, and the optical transmission structure comprises: a first waveguide and a second waveguide extending along a first direction; and at least two racetrack-shaped resonant structures arranged along a second direction different from the first direction and disposed between the first and second waveguides, wherein the at least two racetrack-shaped resonant structures are configured to optically couple the first waveguide to the second waveguide in the second direction; forming a filling layer on a first surface of the photonic die; forming a plurality of conductive connectors on a second surface of the photonic die opposite to the first surface; and bonding a package substrate to the second surface of the photonic die through the plurality of conductive connectors.

In some embodiments, the first waveguide, the second waveguide, and the at least two racetrack-shaped resonant structures are physically separated from each other in the second direction. In some embodiments, the first waveguide, the second waveguide, and the at least two racetrack-shaped resonant structures have the same material. In some embodiments, the first waveguide, the second waveguide, and the at least two racetrack-shaped resonant structures are formed by silicon or silicon nitride.

According to some embodiments, an optical transmission structure includes: a first waveguide and a second waveguide extending along a first direction; and at least two racetrack-shaped resonant structures arranged along a second direction different from the first direction and disposed between the first and second waveguides, wherein the at least two racetrack-shaped resonant structures are configured to optically couple the first waveguide to the second waveguide in the second direction.

In some embodiments, the first waveguide, the second waveguide, and the at least two racetrack-shaped resonant structures are physically separated from each other in the second direction. In some embodiments, the first waveguide, the second waveguide, and the at least two racetrack-shaped resonant structures have the same material. In some embodiments, the first waveguide, the second waveguide, and the at least two racetrack-shaped resonant structures are made of silicon or silicon nitride. In some embodiments, the first waveguide, the second waveguide, and the at least two racetrack-shaped resonant structures are at the same level, so that an optical signal is transmitted horizontally on the same plane.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
an electronic die; and
a photonic die bonding to the electronic die, wherein the photonic die comprises:
a substrate;
an interconnect structure disposed over the substrate;
a semiconductor layer disposed between the substrate and the interconnect structure, wherein the semiconductor layer comprises:
a first waveguide and a second waveguide extending along a first direction; and
at least two ring resonant structures arranged along a second direction different from the first direction and disposed between the first and second waveguides, wherein the at least two ring resonant structures are configured to optically couple the first waveguide to the second waveguide in the second direction.

2. The package structure of claim 1, wherein the first direction is substantially orthogonal to the second direction.

3. The package structure of claim 1, wherein the at least two ring resonant structures are racetrack-shaped in a top view of the semiconductor layer, and an overlapping length of facing sidewalls of the at least two ring resonant structures in the first direction is at least greater than zero.

4. The package structure of claim 1, wherein the at least two ring resonant structures are racetrack-shaped in a top view of the semiconductor layer, and the at least two ring resonant structures are completely aligned and overlapped with each other in the second direction.

5. The package structure of claim 1, wherein the at least two ring resonant structures, the first waveguide, and the second waveguide are physically separated from each other in the second direction.

6. The package structure of claim 1, wherein the at least two ring resonant structures have the same racetrack shape in a top view of the semiconductor layer.

7. The package structure of claim 1, wherein the semiconductor layer is a silicon layer.

8. The package structure of claim 1, further comprising:
a coupler optically connected to the first waveguide;
a first photodetector optically connected to the first waveguide; and
a second photodetector optically connected to the second waveguide.

9. The package structure of claim 1, wherein further comprising:
a dielectric layer embedded in the substrate, wherein the dielectric layer comprises at least two racetrack-shaped resonant structures.

10. The package structure of claim 1, wherein the at least two racetrack-shaped resonant structures are optically coupled to the semiconductor layer in a vertical manner.

11. The package structure of claim 1, wherein a material of the dielectric layer is silicon nitride.

12. A method of forming a package structure, comprising:
bonding an electronic die to a photonic die, wherein the photonic die comprises an optical transmission structure, and the optical transmission structure comprises:
a first waveguide and a second waveguide extending along a first direction; and
at least two racetrack-shaped resonant structures arranged along a second direction different from the first direction and disposed between the first and second waveguides, wherein the at least two racetrack-shaped resonant structures are configured to optically couple the first waveguide to the second waveguide in the second direction;
forming a filling layer on a first surface of the photonic die;
forming a plurality of conductive connectors on a second surface of the photonic die opposite to the first surface; and
bonding a package substrate to the second surface of the photonic die through the plurality of conductive connectors.

13. The method of claim 12, wherein the first waveguide, the second waveguide, and the at least two racetrack-shaped resonant structures are physically separated from each other in the second direction.

14. The method of claim 12, wherein the first waveguide, the second waveguide, and the at least two racetrack-shaped resonant structures have the same material.

15. The method of claim 12, wherein the first waveguide, the second waveguide, and the at least two racetrack-shaped resonant structures are formed by silicon or silicon nitride.

16. An optical transmission structure, comprising:
a first waveguide and a second waveguide extending along a first direction; and
at least two racetrack-shaped resonant structures arranged along a second direction different from the first direction and disposed between the first and second waveguides, wherein the at least two racetrack-shaped resonant structures are configured to optically couple the first waveguide to the second waveguide in the second direction.

17. The optical transmission structure of claim 16, wherein the first waveguide, the second waveguide, and the at least two racetrack-shaped resonant structures are physically separated from each other in the second direction.

18. The optical transmission structure of claim 16, wherein the first waveguide, the second waveguide, and the at least two racetrack-shaped resonant structures have the same material.

19. The optical transmission structure of claim 16, wherein the first waveguide, the second waveguide, and the at least two racetrack-shaped resonant structures are made of silicon or silicon nitride.

20. The optical transmission structure of claim 16, wherein the first waveguide, the second waveguide, and the at least two racetrack-shaped resonant structures are at the same level, so that an optical signal is transmitted horizontally on the same plane.
